(19) United States
(12) Patent Application Publication
(10) Pub. No.: US 2026/0112395 A1
(43) Pub. Date: Apr. 23, 2026

(54) SEMICONDUCTOR DEVICE AND MANUFACTURING METHOD OF SEMICONDUCTOR DEVICE

(71) Applicant: Samsung Electronics Co., Ltd., Suwon-si (KR)

(72) Inventors: Yuna Gil, Suwon-si (KR); Woohyun Park, Suwon-si (KR); Sung-Ho Eun, Suwon-si (KR)

(21) Appl. No.: 19/252,265

(22) Filed: Jun. 27, 2025

(30) Foreign Application Priority Data
Oct. 21, 2024 (KR) 10-2024-0144116

(51) Int. Cl. G11C 5/06; H10B 63/00; H10N 70/00

(52) U.S. Cl. CPC G11C 5/063; H10B 63/20; H10B 63/84; H10N 70/063

(57) ABSTRACT

A semiconductor device includes a first signal line extending in a first direction; a second signal line extending in a second direction, the second direction crossing the first direction, the second signal line on the first signal line in a third direction perpendicular to the first direction and the second direction; a memory cell positioned between the first signal line and the second signal line in the third direction; and a first insulating layer at least partially surrounding the memory cell, wherein the first insulating layer may include a first sub-insulating layer overlapping the second signal line in the third direction and a second sub-insulating layer overlapping the first signal line in the third direction, and the first sub-insulating layer and the second sub-insulating layer may include different materials.

### CROSS-REFERENCE TO RELATED APPLICATION

This application claims priority to and the benefit of Korean Patent Application No. 10-2024-0144116, filed in the Korean Intellectual Property Office on Oct. 21, 2024, the entire contents of which are incorporated herein by reference.

### TECHNICAL FIELD

The present disclosure relates to a semiconductor device and a manufacturing method thereof.

### BACKGROUND

A semiconductor is a material including characteristics between a conductor and an insulator and refers to a material that conducts electricity under a predetermined condition. Various semiconductor devices can be manufactured by using such a semiconductor material, and for example, a memory device and the like can be manufactured. Such a semiconductor device may be used in various electronic devices.

In the semiconductor industry, demand for high-capacity, thinner, and smaller semiconductor devices and associated electronic products is increasing.

As semiconductor devices become higher capacity, thinner, and more miniaturized, the difficulty of the manufacturing process increases, which in turn complicates the manufacturing process and increases the manufacturing process time.

### SUMMARY

Embodiments provide a semiconductor device and a manufacturing method for a semiconductor device that may simplify a manufacturing process and reduce a manufacturing time without reducing performance of the semiconductor device.

However, the problem to be solved by the embodiments is not limited to the above-described problem and can be variously extended within the scope of the description of the embodiments.

An embodiment of the present disclosure provides a semiconductor device including: a first signal line extending in a first direction; a second signal line extending in a second direction, the second direction crossing the first direction, the second signal line on the first signal line in a third direction perpendicular to the first direction and the second direction; a memory cell positioned between the first signal line and the second signal line in the third direction; and a first insulating layer at least partially surrounding the memory cell, wherein the first insulating layer may include a first sub-insulating layer overlapping the second signal line in the third direction and a second sub-insulating layer overlapping the first signal line in the third direction, and the first sub-insulating layer and the second sub-insulating layer may include different materials.

An embodiment of the present disclosure provides a manufacturing method for a semiconductor device, including: forming a first signal line extending in a first direction and forming a third insulating layer on a side surface of the first signal line; forming a memory layer extending parallel to the first signal line on the first signal line; and forming a preliminary insulating layer on a side surface of the memory layer and on the third insulating layer; stacking a metal layer on the memory layer and the first sub-insulating layer; forming a second signal line extending in a second direction crossing the first direction, a memory cell between the first signal line and the second signal line, and a first sub-insulating layer below the second signal line and on a first side surface of the memory cell by etching the memory layer and the preliminary insulating layer together with the metal layer; and forming a second insulating layer on a side surface of the second signal line and a second sub-insulating layer on a second side surface of the memory cell, wherein the first sub-insulating layer and the second sub-insulating layer may include different materials.

According to the embodiments, a semiconductor device and a manufacturing method for a semiconductor device is provided that may simplify a manufacturing process and reduce a manufacturing time without reducing performance of the semiconductor device.

However, the effect of the embodiments is not limited to the above-described effect, and may be variously extended without departing from the scope of the embodiments.

### BRIEF DESCRIPTION OF THE DRAWINGS

FIG. 1 illustrates a 3D perspective view of a semiconductor device according to embodiments of the present disclosure.

FIG. 2 and FIG. 3 illustrate cross-sectional views showing a portion of the semiconductor device of FIG. 1.

FIG. 4 to FIG. 7 illustrate perspective views showing a manufacturing method for a semiconductor device according to embodiments of the present disclosure.

FIG. 8 to FIG. 11 illustrate cross-sectional views showing a manufacturing method for a semiconductor device according to embodiments of the present disclosure.

FIG. 12 and FIG. 13 illustrate perspective views showing a manufacturing method for a semiconductor device according to embodiments of the present disclosure.

FIG. 14 illustrates a block diagram showing a semiconductor device according to embodiments of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

To clearly describe the present disclosure, like numerals refer to like or similar components throughout the specification.

The accompanying drawings are provided only in order to allow embodiments disclosed in the present specification to be easily understood and are not to be interpreted as limiting the scope of the present specification, and it is to be understood that this disclosure includes all modifications, equivalents, and substitutions within the scope of this disclosure.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” means that two or more components may be directly connected, or two or more components may be connected indirectly through other components. “Connected” may refer to physically connected and/or electrically connected, and in some instances may mean integrally connected.

Components or layers described with reference to “overlap” in a particular direction may be at least partially obstructed by one another when viewed along a line extending in the particular direction or in a plane perpendicular to the particular direction. The terms “first,” “second,” etc., may be used herein merely to distinguish one component, layer, direction, etc. from another. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout.

Hereinafter, various embodiments and variations will be described in detail with reference to drawings.

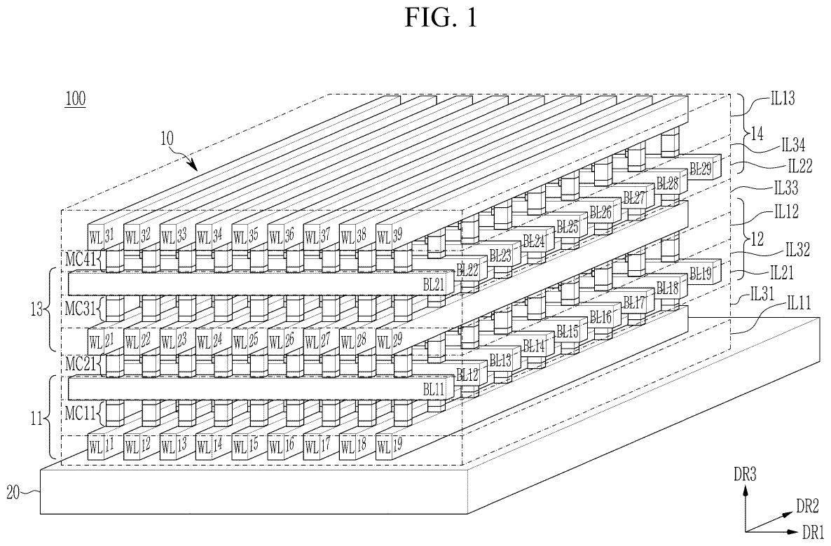

A semiconductor device according to an embodiment will now be described with reference to FIG. 1. FIG. 1 illustrates a 3D perspective view of a semiconductor device according to an embodiment.

Referring to FIG. 1, a semiconductor device 100 according to an embodiment may include a memory cell array 10 and a peripheral circuit 20.

The semiconductor device 100 of FIG. 1 may be a memory device on a wafer, or a semiconductor device separated from the wafer and combined with other components.

The memory cell array 10 may have a multi-deck structure. According to the embodiment, the memory cell array 10 may include multiple memory layers. Referring to FIG. 1, the memory cell array 10 according to the embodiment may include a first memory layer 11, a second memory layer 12, a third memory layer 13, and a fourth memory layer 14, but embodiments are not limited thereto, and the number of memory layers included in the memory cell array 10 may vary. A structure of the memory cell array 10 illustrated in FIG. 1 is an example for describing an embodiment, and embodiments are not limited thereto.

The memory cell array 10 may include a plurality of memory cells respectively arranged in regions where a plurality of first signal lines and a plurality of second signal lines intersect. In an embodiment, a first signal line may be a first one of a bit line and a word line, and a second signal line may be a second one of the bit line and the word line. Each of the memory cells may be a single level cell that stores one bit, or a multi-level cell that can store at least two bits of data. Furthermore, the memory cells may have multiple resistance distributions depending on a number of bits stored in each of the memory cells. For example, when each memory cell stores one bit of data, the memory cells may have two resistance distributions, and when each memory cell stores two bits of data, the memory cells may have four resistance distributions.

The memory cells may be a resistive memory cell including a variable resistor element. For example, a variable resistor element may include a phase change material, and a resistive memory device may be a phase-change memory (PRAM) having a resistance that changes with temperature. For example, the variable resistor element may include an upper electrode, a lower electrode, and a complex metal oxide therebetween, and the resistive memory device may be a resistive RAM (RRAM). For example, the variable resistor element may include an upper electrode of a magnetic material, a lower electrode of a magnetic material, and a dielectric therebetween, and the resistive memory device may be a magnetic RAM (MRAM). Memory cells of some embodiments of the present disclosure may be resistive memory cells.

The peripheral circuit 20 may be positioned below the memory cell array 10 and may be electrically connected to the memory cell array 10. For example, multiple memory layers 11, 12, 13, and 14 may be sequentially positioned on the peripheral circuit 20. The peripheral circuit 20 may include a plurality of wires connected to a first plurality of bit lines BL11, BL12, BL13, BL14, BL15, BL16, BL17, BL18, and BL19, and a second plurality of bit lines BL21, BL22, BL23, BL24, BL25, BL26, BL27, BL28, and BL29, and a plurality of wires connected to a first plurality of word lines WL11, WL12, WL13, WL14, WL15, WL16, WL17, WL18, and WL19, a second plurality of word lines WL21, WL22, WL23, WL24, WL25, WL26, WL27, WL28, and WL29, and a third plurality of word lines WL31, WL32, WL33, WL34, WL35, WL36, WL37, WL38, and WL39. Voltage may be applied to each of the first and second pluralities of bit lines BL11, BL12, BL13, BL14, BL15, BL16, BL17, BL18, and BL19, and BL21, BL22, BL23, BL24, BL25, BL26, BL27, BL28, and BL29 and each of the first, second, and third pluralities of word lines WL11, WL12, WL13, WL14, WL15, WL16, WL17, WL18, and WL19, WL21, WL22, WL23, WL24, WL25, WL26, WL27, WL28, and WL29, and WL31, WL32, WL33, WL34, WL35, WL36, WL37, WL38, and WL39 through a plurality of wires of the peripheral circuit 20. As used herein, BL11 to BL19 may refer to the plurality of first bit lines BL11, BL12, BL13, BL14, BL15, BL16, BL17, BL18, and BL19; BL21 to BL29 may refer to the plurality of second bit lines BL21, BL22, BL23, BL24, BL25, BL26, BL27, BL28, and BL29; WL11 to WL19 may refer to the plurality of first word lines WL11, WL12, WL13, WL14, WL15, WL16, WL17, WL18, and WL19; WL 21 to WL may refer to the plurality of second word lines WL21, WL22, WL23, WL24, WL25, WL26, WL27, WL28, and WL29; and WL31 to WL39 may refer to the plurality of third word lines WL31, WL32, WL33, WL34, WL35, WL36, WL37, WL38, and WL39.

The memory cell array 10 may include the memory layers 11, 12, 13, and 14, and two adjacent memory layers among the memory layers 11, 12, 13, 14 may share the bit lines BL11 to BL19 and BL21 to BL29 or the word lines WL11 to WL19, WL21 to WL29, and WL31 to WL39.

The bit lines BL11 to BL19 and BL21 to BL29 may include the first bit lines BL11 to BL19 and the second bit lines BL21 to BL29 extending in the first direction DR1.

The first bit lines BL11 to BL19 may be shared between the first memory layer 11 and the second memory layer 12.

The second bit lines BL21 to BL29 may be shared with the third memory layer 13 and the fourth memory layer 14.

The word lines WL11 to WL19, WL21 to WL29, and WL31 to WL39 may extend in the second direction DR2. The word lines WL11 to WL19, WL21 to WL29, and WL31 to WL39 may include a plurality of first word lines WL11 to WL19, a plurality of second word lines WL21 to WL29, and a plurality of third word lines WL31 to WL39.

The first word lines WL11 to WL19 may be positioned on the peripheral circuit 20 and may be connected to the first memory layer 11.

The second word lines WL21 to WL29 may be shared by the second memory layer 12 and the third memory layer 13. The third word lines WL31 to WL39 may be shared by the third memory layer 13 and the fourth memory layer 14.

The memory cells MC11, MC21, MC31, and MC41 may be positioned in a plurality of regions where the bit lines BL11 to BL19 and BL21 to BL29 and the word lines WL11 to WL19, WL21 to WL29, and WL31 to WL39 intersect.

The memory cells MC11, MC21, MC31, and MC41 may include a plurality of first memory cells MC11 positioned in regions where the first word lines WL11 to WL19 and the first bit lines BL11 to BL19 intersect each other, a plurality of second memory cells MC21 positioned in regions where the first bit lines BL11 to BL19 and the second word lines WL21 to WL29 intersect each other, a plurality of third memory cells MC31 positioned in regions where the second word lines WL21 to WL29 and the second bit lines BL21 to BL29 intersect each other, and a plurality of fourth memory cells MC41 positioned in regions where the second bit lines BL21 to BL29 and the third word lines WL31 to WL39 intersect each other.

The memory cell array 10 may be protected by insulating layers IL11, IL12, IL13, IL21, IL22, IL31, IL32, IL33, and IL34.

The insulating layers IL11, IL12, IL13, IL21, IL22, IL31, IL32, IL33, and IL34 may include insulating layers IL11 positioned on side surfaces of the first word lines WL11 to WL19 respectively, insulating layers IL12 positioned on side surfaces of the second word lines WL21 to WL29 respectively, insulating layers IL13 positioned on side surfaces of the third word lines WL31 to WL39 respectively, insulating layers IL21 positioned on side surfaces of the first bit lines BL11 to BL19 respectively, insulating layers IL22 positioned on side surfaces of the second bit lines BL21 to BL29 respectively, insulating layers IL31 positioned on side surfaces of the first memory cells MC11 respectively, insulating layers IL32 positioned on side surfaces of the second memory cells MC21 respectively, insulating layers IL33 positioned on side surfaces of the third memory cells MC31 respectively, and insulating layers IL34 positioned on side surfaces of the fourth memory cells MC41 respectively.

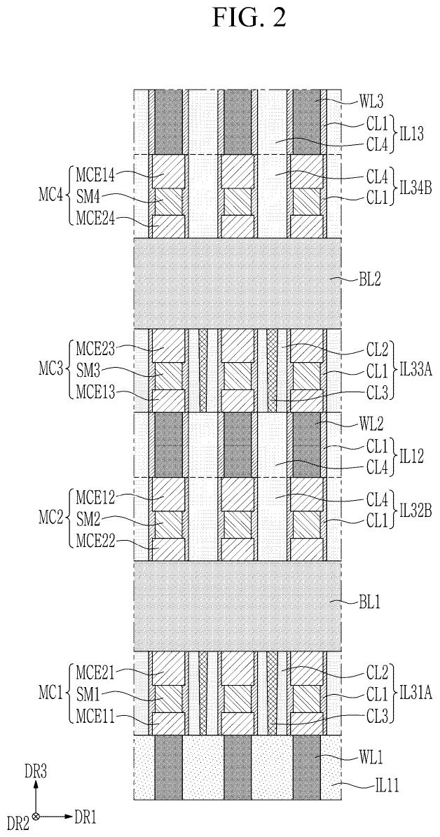

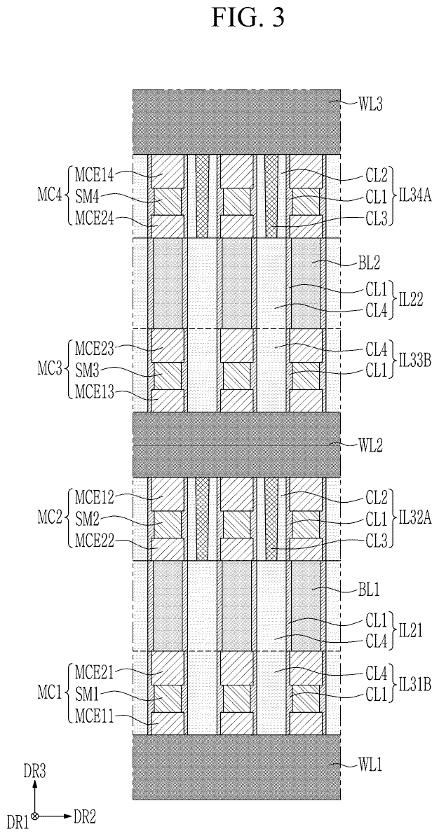

Referring to FIG. 2 and FIG. 3 together with FIG. 1, the semiconductor device 100 according to an embodiment will be described in more detail. FIG. 2 and FIG. 3 illustrate cross-sectional views showing a portion of the semiconductor device of FIG. 1.

FIG. 2 illustrates a cross-sectional view of a portion of FIG. 1 taken in a direction that is parallel to the first direction DR1, and FIG. 3 illustrates a cross-sectional view of a portion of FIG. 1 taken in a direction that is parallel to the second direction DR2.

In FIG. 2, three first word lines WL1 among the first word lines WL11 to WL19, three second word lines WL2 among the second word lines WL21 to WL29, three third word lines WL3 among the word lines WL31 to WL39, one first bit line BL1 among the first bit lines BL11 to BL19, and one second bit line BL2 among the second bit lines BL21 to BL29 are illustrated. Further, three first memory cells MC1 among the first memory cells MC11, three second memory cells MC2 among the second memory cells MC21, three third memory cells MC3 among the third memory cells MC31, and three fourth memory cells MC4 among the fourth memory cells MC41 are illustrated.

In FIG. 3, one first word line WL1 among the first word lines WL11 to WL19, one second word line WL2 among the second word lines WL21 to WL29, one third word line WL3 among the third word lines WL31 to WL39, three first bit lines BL1 among the first bit lines BL11 to BL19, and three second bit lines BL2 among the second bit lines BL21 to BL29 are illustrated. Furthermore, three first memory cells MC1 among the first memory cells MC11, three second memory cells MC2 among the second memory cells MC21, three third memory cells MC3 among the third memory cells MC31, and three fourth memory cells MC4 among the fourth memory cells MC41 are illustrated.

Referring to FIGS. 2 and 3 together with FIG. 1, the insulating layers IL11 may be positioned on side surfaces of the first word lines WL1, and the insulating layers IL21 may be positioned on side surfaces of the first bit lines BL1. The insulating layers IL11 may be positioned between the first word lines WL1 and may extend in a direction parallel to the second direction DR2 along the first word lines WL1, and the insulating layers IL21 may be positioned between the first bit lines BL1 and may extend in a direction parallel to the first direction DR1 along the first bit lines BL1.

Similarly, the insulating layers IL12 may be positioned on side surfaces of the first word lines WL2, and the insulating layers IL22 may be positioned on side surfaces of the first bit lines BL2. The insulating layers IL12 may be positioned between the second word lines WL2 and may extend in a direction parallel to the second direction DR2 along the second word lines WL2, and the insulating layers IL22 may be positioned between the second bit lines BL2 and may extend in a direction parallel to the first direction DR1 along the second bit lines BL2.

The insulating layers IL13 may be positioned on surfaces of the third word lines WL3. The insulating layers IL13 may be positioned between the third word lines WL3 and may extend in a direction parallel to the second direction DR2 along the third word lines WL3.

The first memory cells MC1 may include first electrodes MCE11 positioned above the first word lines WL1 and connected to the first word lines WL1, second electrodes MCE21 positioned below the first bit lines BL1 and connected to the first bit lines BL1, and switch memories SM1 positioned between the first electrodes MCE11 and the second electrodes MCE21 along a third direction DR3, which is a height direction. The third direction DR3 may be perpendicular to the first direction DR1 and the second direction DR2. Along the third direction DR3, the first electrodes MCE11, the switch memories SM1, and the second electrodes MCE21 may be sequentially stacked. As used herein, to “stack” an element may mean to form or arrange said element on another.

The insulating layers IL31 positioned on side surfaces of the first memory cells MC1 to fill and protect a space between the first memory cells MC1 may include first sub-insulating layers IL31A positioned below the first bit line BL1 and above the insulating layer IL11, and second sub-insulating layers IL31B positioned above the first word line WL1 and below the insulating layer IL21.

The first sub-insulating layers IL31A may include first layers CL1, second layers CL2, and third layers CL3. The first layers CL1 may be positioned on sidewalls of the first memory cells MC1, the second layers CL2 may be positioned on side surfaces of the first layers CL1, and the third layers CL3 may be positioned between the second layers CL2.

Two first layers CL1 may be positioned between two adjacent first memory cells MC1, two second layers CL2 may be positioned between two first layers CL1, and one third layer CL3 may be positioned between two second layers CL2.

The first layers CL1 and the second layers CL2 may contain a same material, and the third layers CL3 may contain a different material from those of the first layers CL1 or the second layers CL2. However, embodiments are not limited thereto.

The second sub-insulating layers IL31B may include first layers CL1 and fourth layers CL4. The first layers CL1 may be positioned on sidewalls of the first memory cells MC1, and the fourth layers CL4 may be positioned on side surfaces of the first layers CL1.

Two first layers CL1 may be positioned between two adjacent first memory cells MC1, and one fourth layers CL4 may be positioned between two first layers CL1.

The first layers CL1 and the fourth layers CL4 may contain a same material, and the first layers CL1 and the fourth layers CL4 may contain a different material from that of the third layer CL3. However, embodiments are not limited thereto.

The third layers CL3 may be or may include material(s) that have a lower dielectric constant than that of the fourth layers CL4. For example, the third layers CL3 may include a low-k dielectric material, that is, a material having a dielectric constant that is lower than that of silicon dioxide. In some embodiments, the third layers CL3 may include a silicon oxycarbide (SiOC), and the fourth layers CL4 may include a silicon nitride (SiN). However, embodiments are not limited thereto.

The insulating layers IL21 positioned on the second sub-insulating layers IL31B may include first layers CL1 and fourth layers CL4 like the second sub-insulating layers IL31B.

The second sub-insulating layers IL31B and the insulating layers IL21 may be connected to each other, and the second sub-insulating layers IL31B may extend in a direction parallel to the first direction DR1 along the first bit lines BL1 together with the insulating layers IL21.

The second memory cells MC2 may include first electrodes MCE12 positioned below the second word lines WL2 and connected to the second word lines WL2, second electrodes MCE22 positioned above the first bit lines BL1 and connected to the first bit lines BL1, and switch memories SM2 positioned between the first electrodes MCE12 and the second electrodes MCE22.

The insulating layers IL31 positioned on side surfaces of the first memory cells MC1 may include first sub-insulating layers IL32A positioned below the second word line WL2 and above the insulating layers IL21, and second sub-insulating layers IL32B positioned above the first bit line BL1 and below the insulating layers IL12.

The first sub-insulating layers IL32A may include first layers CL1, second layers CL2, and third layers CL3. The first layers CL1 may be positioned on sidewalls of the second memory cells MC2, the second layers CL2 may be positioned on side surfaces of the first layers CL1, and the third layers CL3 may be positioned between the second layers CL2.

Two first layers CL1 may be positioned between two second memory cells MC2, two adjacent second layers CL2 may be positioned between two first layers CL1, and one third layer CL3 may be positioned between two second layers CL2.

The first layers CL1 and the second layers CL2 may contain a same material, and the third layers CL3 may contain a different material from those of the first layers CL1 or the second layer CL2. However, embodiments are not limited thereto.

The second sub-insulating layers IL32B may include first layers CL1 and fourth layers CL4. The first layers CL1 may be positioned on sidewalls of the second memory cells MC2, and the fourth layers CL4 may be positioned on side surfaces of the first layers CL1.

Two first layers CL1 may be positioned between two adjacent second memory cells MC2, and one fourth layers CL4 may be positioned between two first layers CL1.

The first layers CL1 and the fourth layers CL4 may contain a same material, and the first layers CL1 and the fourth layers CL4 may contain a different material from that of the third layers CL3. However, embodiments are not limited thereto.

The insulating layers IL12 positioned on the second sub-insulating layer IL32B may include first layers CL1 and fourth layers CL4 like the second sub-insulating layers IL32B.

The second sub-insulating layers IL32B and the insulating layers IL12 may be connected to each other, and the second sub-insulating layers IL32B may extend in a direction parallel to the second direction DR2 along the second bit lines BL2 together with the insulating layers IL12.

The third memory cells MC3 may include first electrodes MCE13 positioned above and connected to the second word lines WL2, second electrodes MCE23 positioned below and connected to the second bit lines BL2, and switch memories SM3 positioned between the first electrodes MCE13 and the second electrodes MCE23.

The insulating layers IL33 positioned on side surfaces of the third memory cells MC3 to fill and protect a space between the third memory cells MC3 may include first sub-insulating layers IL33A positioned below the second bit line BL2 and above the insulating layers IL12, and second sub-insulating layers IL33B positioned above the second word line WL2 and below the insulating layers IL22.

The first sub-insulating layers IL33A may include first layers CL1, second layers CL2, and third layers CL3. The first layers CL1 may be positioned on sidewalls of the third memory cells MC3, the second layers CL2 may be positioned on side surfaces of the first layers CL1, and the third layers CL3 may be positioned between the second layers CL2.

Two first layers CL1 may be positioned between two adjacent third memory cells MC3, two third layers CL2 may be positioned between two first layers CL1, and one third layer CL3 may be positioned between two second layers CL2.

The first layers CL1 and the second layers CL2 may contain a same material, and the third layers CL3 may contain a different material from those of the first layers CL1 or the second layers CL2. However, embodiments are not limited thereto.

The second sub-insulating layers IL33B may include first layers CL1 and fourth layers CL4. The first layers CL1 may be positioned on sidewalls of the third memory cells MC3, and the fourth layers CL4 may be positioned on side surfaces of the first layers CL1.

Two first layers CL1 may be positioned between two adjacent third memory cells MC3, and one fourth layers CL4 may be positioned between two first layers CL1.

The first layers CL1 and the fourth layers CL4 may contain a same material, and the first layers CL1 and the fourth layers CL4 may contain a different material from that of the third layers CL3. However, embodiments are not limited thereto.

The insulating layers IL22 positioned on the second sub-insulating layers IL33B may include first layers CL1 and fourth layers CL4 like the second sub-insulating layers IL33B.

The second sub-insulating layers IL33B and the insulating layers IL22 may be connected to each other, and the second sub-insulating layers IL33B may extend in a direction parallel to the first direction DR1 along the second bit lines BL2 together with the insulating layers IL22.

The fourth memory cells MC4 may include first electrodes MCE14 positioned below the third word lines WL3 and connected to the third word lines WL3, second electrodes MCE24 positioned above the third bit lines BL2 and connected to the third bit lines BL2, and switch memories SM4 positioned between the first electrodes MCE14 and the second electrodes MCE24.

The insulating layers IL34 positioned on side surfaces of the fourth memory cells MC4 may include first sub-insulating layers IL34A positioned below the third word line WL3 and above the insulating layers IL22, and second sub-insulating layers IL34B positioned above the second bit line BL2 and below the insulating layers IL13.

The first sub-insulating layers IL34A may include first layers CL1, second layers CL2, and third layers CL3. The first layers CL1 may be positioned on sidewalls of the fourth memory cells MC4, the second layers CL2 may be positioned on side surfaces of the first layers CL1, and the third layers CL3 may be positioned between the second layers CL2.

Two first layers CL1 may be positioned between two adjacent fourth memory cells MC4, two third layers CL2 may be positioned between two first layers CL1, and one third layer CL3 may be positioned between two second layers CL2.

The first layers CL1 and the second layers CL2 may contain a same material, and the third layers CL3 may contain a different material from those of the first layers CL1 or the second layers CL2. However, embodiments are not limited thereto.

The second sub-insulating layers IL34B may include first layers CL1 and fourth layers CL4. The first layers CL1 may be positioned on sidewalls of the fourth memory cells MC4, and the fourth layers CL4 may be positioned on side surfaces of the first layers CL1.

Two first layers CL1 may be positioned between two adjacent fourth memory cells MC4, and one fourth layers CL4 may be positioned between two first layers CL1.

The first layers CL1 and the fourth layers CL4 may contain a same material, and the first layers CL1 and the fourth layers CL4 may contain a different material from that of the third layers CL3. However, embodiments are not limited thereto.

The insulating layers IL13 positioned on the second sub-insulating layers IL34B may include first layers CL1 and fourth layers CL4 like the second sub-insulating layers IL34B.

The second sub-insulating layers IL34B and the insulating layers IL13 may be connected to each other, and the second sub-insulating layers IL34B may extend in a direction parallel to the second direction DR2 along the third word lines BL3 together with the insulating layers IL13.

According to an embodiment, the insulating layers IL31, IL32, IL33, and IL34 positioned on side surfaces of the memory cells MC1, MC2, MC3, and MC4 to fill and protect regions between the memory cells MC1, MC2, MC3, and MC4 may include: first sub-insulating layers IL31A, IL32A, IL33A, and IL34A positioned above the insulating layers between the signal lines positioned below the memory cells MC1, MC2, MC3, and MC4 to overlap the signal lines along the height direction and positioned below the signal lines positioned above the memory cells MC1, MC2, MC3, and MC4 to overlap the signal lines along the height direction; and second sub-insulating layers IL31B, IL32B, IL33B, and IL34B positioned above the signal lines positioned below the memory cells MC1, MC2, MC3, and MC4 to overlap the signal lines along the height direction and positioned below the insulating layers between the signal lines positioned above the memory cells MC1, MC2, MC3, and MC4 to overlap the signal lines along the height direction. The second sub-insulating layers IL31B, IL32B, IL33B, and IL34B may be formed together with the insulating layers positioned between the signal lines positioned above the memory cells MC1, MC2, MC3, and MC4.

The first sub-insulating layers IL31A, IL32A, IL33A, and IL34A and the second sub-insulating layers IL31B, IL32B, IL33B, and IL34B may include different layers.

The first sub-insulating layers IL31A, IL32A, IL33A, and IL34A may include first layers CL1, second layers CL2, and third layers CL3, and the second sub-insulating layers IL31B, IL32B, IL33B, and IL34B may include first layers CL1 and fourth layers CL4.

The first layers CL1 and the second layers CL2 may include a same material, the third layers CL3 may include a different material from those of the first layers CL1 or the second layers CL2. The first layers CL1 and the fourth layers CL4 may include a same material, or the first layers CL1 and the fourth layers CL4 may include a different material from that of the third layer CL3. However, embodiments are not limited thereto.

The third layers CL3 may have a lower dielectric constant than that of the fourth layers CL4. For example, the third layers CL3 may include a low-k dielectric material. In some embodiments, the third layers CL3 may include a silicon oxycarbide (SiOC), and the fourth layers CL4 may include a silicon nitride (SiN). However, embodiments are not limited thereto.

In this way, the first sub-insulating layers IL31A, IL32A, IL33A, and IL34A including the third layers CL3 having a low dielectric constant among the insulating layers IL31, IL32, IL33, and IL34 that fill and protect regions between the memory cells MC1, MC2, MC3, and MC4 are positioned below and overlap the signal lines positioned above the memory cells MC1, MC2, MC3, and MC4, and accordingly may be covered and protected by signal lines during a subsequent etching process. Accordingly, the first sub-insulating layers IL31A, IL32A, IL33A, and IL34A may not be unnecessarily or unintentionally etched during the subsequent process, and thus a process of stacking an additional insulating layer to fill an etched portion during the subsequent process may be omitted. Further, among the insulating layers IL31, IL32, IL33, IL34 that fill and protect the regions between the memory cells MC1, MC2, MC3, and MC4, the first sub-insulating layers IL31A, IL32A, IL33A, and IL34A may include the third layer CL3 having a low dielectric constant, so signal interference of the semiconductor device may be reduced.

Further, the second sub-insulating layers IL31B, IL32B, IL33B, and IL34B including the fourth layer CL4 among the insulating layers IL31, IL32, IL33, and IL34 that fill and protect the regions between the memory cells MC1, MC2, MC3, and MC4 may not be easily etched in the etching process compared to the third layer CL3. In this way, the second sub-insulating layers IL31B, IL32B, IL33B, and IL34B, which may not be easily etched during a subsequent process, may be positioned above signal lines (also referred to as underlying signal lines) that are positioned under the memory cells MC1, MC2, MC3, and MC4, thereby preventing the signal lines positioned under the second sub-insulating layers IL31B, IL32B, IL33B, and IL34B from being damaged by an etching solution during a subsequent process. Further, the second sub-insulating layers IL31B, IL32B, IL33B, and IL34B may be formed together with the insulating layers positioned between the signal lines positioned above (also referred to as overlying signal lines) the memory cells MC1, MC2, MC3, and MC4. Accordingly, the manufacturing process may be simplified, and damage to the signal lines during the manufacturing process may be prevented.

As described above, in accordance with the semiconductor device 100 according to the embodiment, the manufacturing process of the semiconductor device may be simplified, damage to signal lines or insulating layers may be prevented during the manufacturing process, and deterioration of insulating characteristics between memory cells may be prevented.

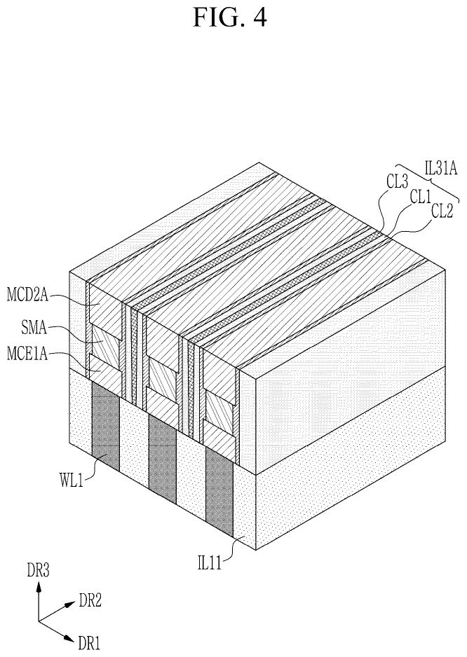

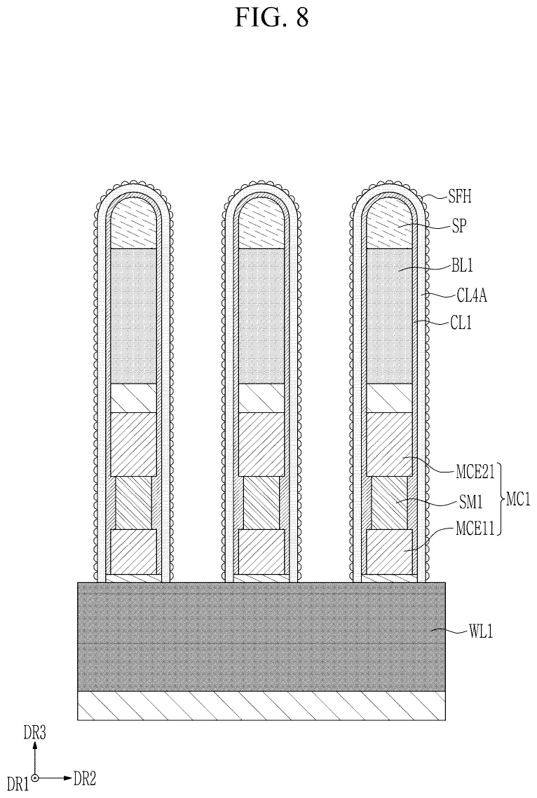

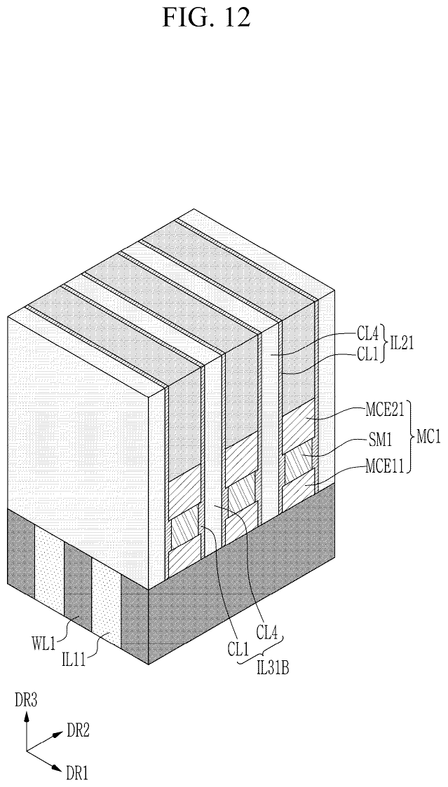

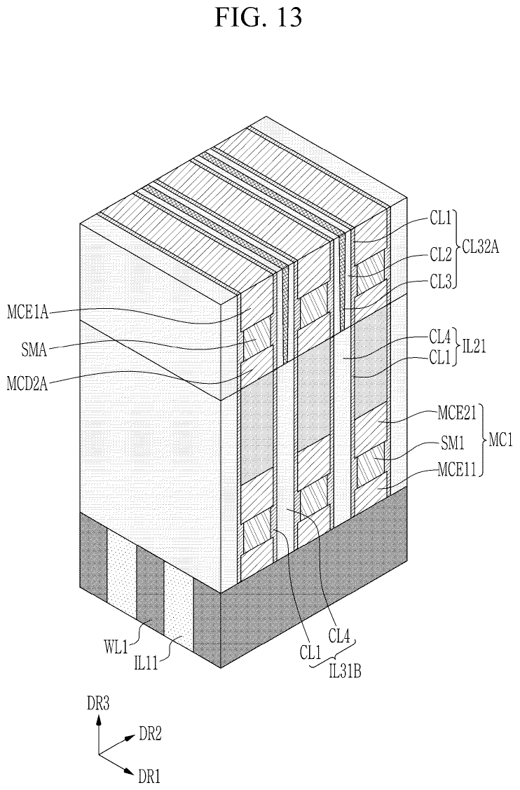

A manufacturing method for a semiconductor device according to an embodiment will be described with reference to FIGS. 1 to 3, FIGS. 4 to 7, FIGS. 8 to 11, and FIGS. 12 and 13. FIG. 4 to FIG. 7 illustrate perspective views showing a manufacturing method for a semiconductor device according an embodiment, FIG. 8 to FIG. 11 illustrate cross-sectional views showing a manufacturing method for a semiconductor device according an embodiment, and FIG. 12 and FIG. 13 illustrate perspective views showing a manufacturing method for a semiconductor device according an embodiment.

Referring to FIG. 4, the first word lines WL1 may be formed, the insulating layers IL11 that fills and protects the side surfaces of the first word lines WL1 may be formed, a first electrode material layer MCE1A, a switch memory material layer SMA, and a second electrode material layer MCD2A may be sequentially stacked on the first word lines WL1 and the insulating layers IL11, portions of the stacked material layers that overlap the insulating layer IL11 may be etched to be removed, and the first sub-insulating layers IL31A may be formed to fill regions between the first electrode material layer MCE1A, the switch memory material layer SMA, and the second electrode material layer MCD2A that overlap the insulating layer IL11 and remains after etching.

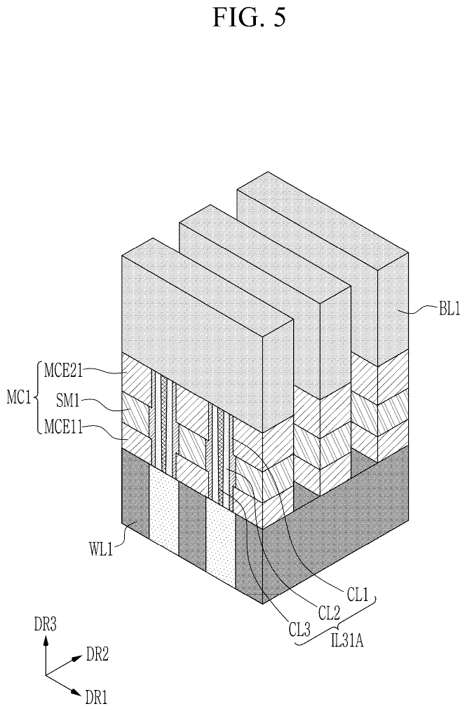

Referring to FIG. 5, a metal layer may be stacked on the second electrode material layer MCD2A and the first sub-insulating layers IL31A, and the first electrode material layer MCE1A, the switch memory material layer SMA, and the second electrode material layer MCD2A may be etched together with the metal layer, thereby the first bit lines BL1 and the first memory cells MC1 may be formed.

In this case, the first sub-insulating layers IL31A may also be etched together, so the first sub-insulating layers IL31A may remain between the first memory cells MC1 and on the insulating layer IL11.

In the first sub-insulating layers IL31A positioned between the first memory cells MC1, portions positioned below the first bit lines BL1 may be covered and protected by the first bit lines BL1 during the etching process, thereby preventing the first sub-insulating layers IL31A from being etched unnecessarily or unintentionally.

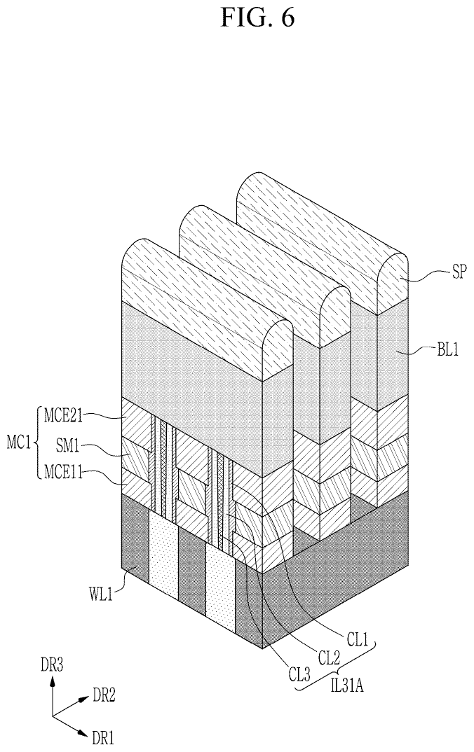

Referring to FIG. 6, spacers SP may be formed on the first bit lines BL1.

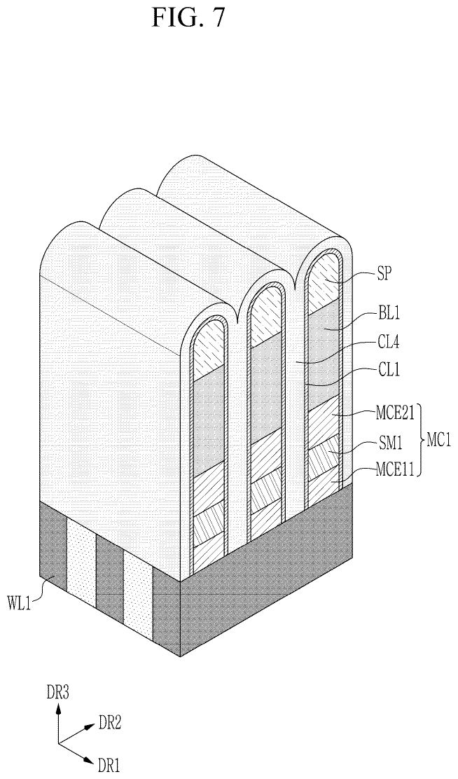

Referring to FIG. 7, the first layers CL1 and the fourth layers CL4 may be stacked between the first memory cells MC1, between the first bit lines BL1, between the spacers SP, and on the spacer SP.

In this case, a method of filling a deep space between the first memory cells MC1 and the first bit lines BL1 with the first layers CL1 and the fourth layers CL4 will be described with reference to FIGS. 8 to 11.

Referring to FIG. 8, the first layers CL1 may be stacked, and a preliminary layer CL4A of the fourth layers CL4 may be stacked thinly and conformally thereon. In this case, a surface of the preliminary layer CL4A may be a hydrogen-terminated surface SFH.

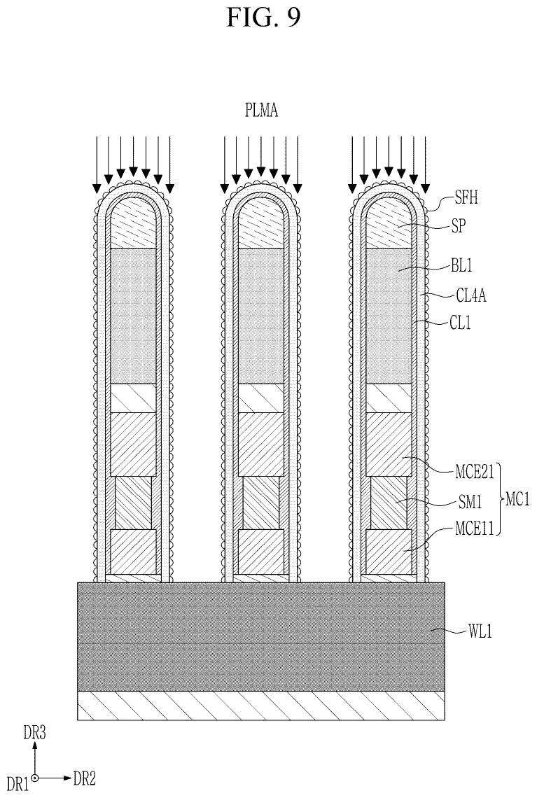

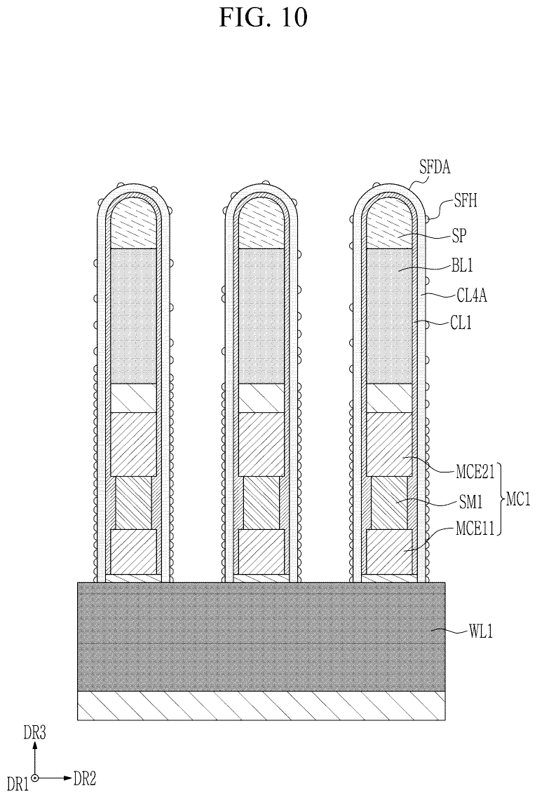

Referring to FIG. 9, nitrogen plasma treatment PLMA may be applied to the hydrogen-terminated surface SFH. When nitrogen plasma treatment PLMA is applied to the hydrogen-terminated surface SFH, at least a portion of the hydrogen-terminated surface SFH may become a deactivated surface SFDA, as illustrated in FIG. 10.

The deactivated surface SFDA may be more abundant on an upper surface with a large amount of nitrogen plasma treatment PLMA and may decrease toward the bottom.

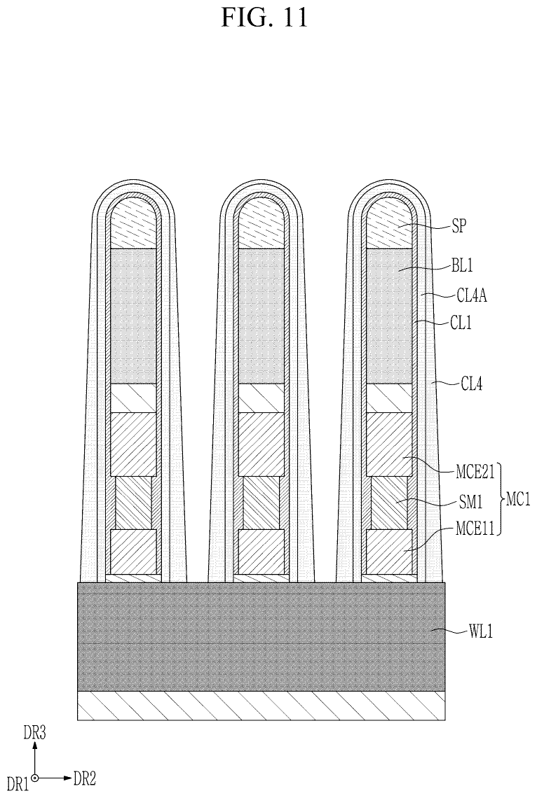

In this way, as a degree of the deactivated surface SFDA decreases with depth, while the fourth layers CL4 are successively stacked on the preliminary layer CL4A, the fourth layers CL4 may be stacked relatively more toward the bottom, as illustrated in FIG. 11. Accordingly, the step coverage is excellent, so the first layers CL1 and the fourth layers CL4 may be filled in the deep spaces between the first memory cells MC1 and the first bit lines BL1.

Referring to FIG. 12, the first layers CL1 and the fourth layers CL4 together with the spacer SP may be removed, so that the insulating layers IL21 that fills and protects the side surfaces of the first bit lines BL1 and a second sub-insulating layer IL31B that fills and protects the side surfaces of the first memory cells MC1 may be formed together. In this way, the insulating layers IL21 and the second sub-insulating layers IL31B may be formed together, the manufacturing process may be simplified.

Referring to FIG. 13, the second electrode material layer MCD2A, the switch memory material layer SMA, and the first electrode material layer MCE1A may be sequentially stacked on the first bit lines BL1 and the insulating layer IL21, and portions of the stacked material layers that overlap the insulating layer IL21 may be etched and removed, and the first sub-insulating layers IL32A may be filled in portions from which the laminated material layers were removed. The first sub-insulating layers IL32A may be filled in regions between the second electrode material layer MCD2A, the switch memory material layer SMA, and the first electrode material layer MCE1A remaining after etching, and the regions filled with the first sub-insulating layers IL32A may overlap the insulating layers IL21.

Herein, the insulating layers IL21 may include the fourth layer CL4 (which may have a comparatively higher etching resistance) rather than the third layer CL3, so during a process of etching the portions of the stacked material layers that overlap the insulating layer IL21, unnecessary damage may not be caused, and a process of forming an additional layer to prevent unnecessary damage may not be required. Accordingly, the manufacturing process may be simplified, and damage to the previously manufactured lower layer during the manufacturing process may be prevented.

Next, as described with reference to FIGS. 5 to 12, the second memory cells MC2 and the second word lines WL2 may be formed, and the second sub-insulating layers IL32B and the insulating layers IL12 may be formed together.

By repeating these processes, a desired number of memory cell stacks may be formed.

In accordance with a manufacturing method for a semiconductor device according to an embodiment, the first sub-insulating layers IL31A, IL32A, IL33A, and IL34A may be covered and protected by the signal lines positioned thereon, so that layers including the third layer CL3 may not be unnecessarily or unintentionally etched in a subsequent process, and thus an additional layer stacking process for protecting the third layer CL3 may be omitted.

Furthermore, the second sub-insulating layers IL31B, IL32B, IL33B, and IL34B and the insulating layers between signal lines positioned above the memory cells may be formed together, accordingly the manufacturing process may be simplified, and the insulating layers may be prevented from being unnecessarily or unintentionally etched in a subsequent etching process.

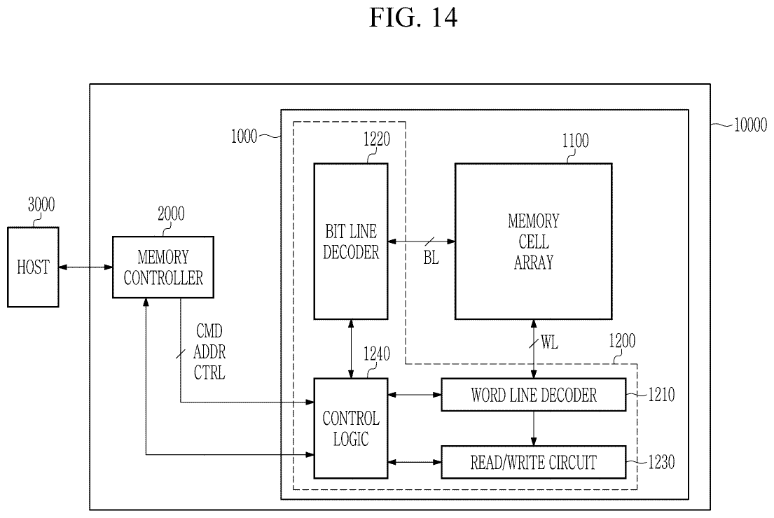

Hereinafter, a semiconductor device 10000 according to an embodiment will be described with reference to FIG. 14. FIG. 14 illustrates a block diagram showing a semiconductor device according to an embodiment.

Referring to FIG. 14, the semiconductor device 10000 according to an embodiment may include a memory device 1000 and a memory controller 2000.

The memory device 1000 may include a memory cell array 1100 and a peripheral circuit 1200. The peripheral circuit 1200 may include decoder circuits 1210 and 1220, a read/write circuit 1230, and a control logic 1240. The memory cell array 1100 may be the memory cell array 10 described above, and the peripheral circuit 1200 may include the peripheral circuit 20 described above.

The memory controller 2000 may generate an address signal ADDR, a command signal CMD, and a control signal CTRL in response to a request from a host 3000 and may provide them to the memory device 1000. The memory controller 2000 may generate the address signal ADDR, the command signal CMD, and the control signal CTRL according to a read request, a write request, an initialization request, etc. from the host 3000.

The memory device 1000 may perform write (or program), read, and initialization operations according to the address signal ADDR, the command signal CMD, and the control signal CTRL. The memory controller 2000 may transmit data signal DATA to be written to the memory device 1000 or receive the data signal DATA read from the memory device 1000 to provide it to the host 3000.

The decoder circuits 1210 and 1220 may include a word line decoder 1210 connected to a plurality of memory cells through word lines WL and a bit line decoder 1220 connected to a plurality of memory cells through bit lines BL. The control logic 1240 may control operations of the word line decoder 1210, the bit line decoder 1220, and the read/write circuit 1230 according to the address signal ADDR, the command signal CMD, and the control signal CTRL. Under control of the control logic 1240, the read/write circuit 1230 may write data to at least one memory cell specified by the word line decoder 1210 and the bit line decoder 1220 and may read data from at least one specified memory cell. The word line decoder 1210 and the bit line decoder 1220 may include the peripheral circuit 20 described above.

When the control logic 1240 receives the command signal CMD instructing an initialization operation, the control logic 1240 may perform an initialization operation on a plurality of memory cells of the memory cell array 1100 through the word line decoder 1210 and the bit line decoder 1220.

While this disclosure has been described in connection with what is presently considered to be practical embodiments, it is to be understood that this disclosure is not limited to the disclosed embodiments, but, on the contrary, is intended to cover various modifications and equivalent arrangements included within the scope of the appended claims.

What is claimed is:

1. A semiconductor device comprising:
a first signal line extending in a first direction;
a second signal line extending in a second direction, the second direction crossing the first direction, the second signal line on the first signal line in a third direction perpendicular to the first direction and the second direction;
a memory cell positioned between the first signal line and the second signal line in the third direction; and
a first insulating layer at least partially surrounding the memory cell,
wherein the first insulating layer comprises a first sub-insulating layer overlapping the second signal line in the third direction and a second sub-insulating layer overlapping the first signal line in the third direction, and
the first sub-insulating layer and the second sub-insulating layer comprise different materials.

2. The semiconductor device of claim 1, further comprising
a second insulating layer on a side surface of the second signal line,
wherein the second sub-insulating layer is directly on the second insulating layer.

3. The semiconductor device of claim 2, wherein
the second sub-insulating layer and the second insulating layer comprise a same layer, and
the second sub-insulating layer extends in the second direction.

4. The semiconductor device of claim 2, further comprising
a third insulating layer on a side surface of the first signal line,
wherein the first sub-insulating layer is on the third insulating layer.

5. The semiconductor device of claim 4, wherein
the first sub-insulating layer and the third insulating layer comprise different layers.

6. The semiconductor device of claim 1, wherein
a dielectric constant of the first sub-insulating layer is lower than a dielectric constant of the second sub-insulating layer.

7. The semiconductor device of claim 6, wherein
the first sub-insulating layer comprises silicon oxycarbide (SiOC), and the second sub-insulating layer comprises silicon nitride (SiN).

8. The semiconductor device of claim 6, wherein
the first sub-insulating layer comprises a first layer positioned on a side surface of the memory cell, a second layer positioned on a side surface of the first layer, and a third layer positioned on a side surface of the second layer.

9. The semiconductor device of claim 8, wherein
the second sub-insulating layer comprises the first layer positioned on a side surface of the memory cell and a fourth layer positioned on a side surface of the first layer.

10. The semiconductor device of claim 1, wherein
the memory cell comprises a first electrode electrically connected to the first signal line, a second electrode electrically connected to the second signal line, and a switch memory between the first electrode and the second electrode.

11. The semiconductor device of claim 10, wherein
the first electrode, the switch memory, and the second electrode overlap each other in the third direction.

12. A manufacturing method for a semiconductor package, comprising:
forming a first signal line extending in a first direction and forming a third insulating layer on a side surface of the first signal line;
forming a memory layer extending parallel to the first signal line on the first signal line, and forming a preliminary insulating layer on a side surface of the memory layer and on the third insulating layer;
stacking a metal layer on the memory layer and the first sub-insulating layer;
forming a second signal line extending in a second direction crossing the first direction, a memory cell between the first signal line and the second signal line, and a first sub-insulating layer below the second signal line and on a first side surface of the memory cell by etching the memory layer and the preliminary insulating layer together with the metal layer; and
forming a second insulating layer on a side surface of the second signal line and a second sub-insulating layer positioned on a second side surface of the memory cell,
wherein the first sub-insulating layer and the second sub-insulating layer comprise different materials.

13. The manufacturing method of claim 12, wherein
the forming of the second insulating layer and the second sub-insulating layer comprises:
stacking a preliminary insulating layer on the side surface of the second signal line and the second side surface of the memory cell;
plasma-treating the preliminary insulating layer; and
stacking a fourth insulating layer on the plasma-treated preliminary insulating layer.

14. The manufacturing method of claim 13, wherein
the plasma-treating comprises a nitrogen plasma treatment.

15. The manufacturing method of claim 12, wherein
the first sub-insulating layer and the third insulating layer comprise different layers.

16. The manufacturing method of claim 15, wherein
the second sub-insulating layer and the second insulating layer comprise a same layer.

17. The manufacturing method of claim 12, wherein
a dielectric constant of the first sub-insulating layer is lower than a dielectric constant of the second sub-insulating layer.

18. The manufacturing method of claim 17, wherein
the first sub-insulating layer comprises a silicon oxycarbide (SiOC), and the second sub-insulating layer comprises a silicon nitride (SiN).

19. The manufacturing method of claim 12, wherein
the memory cell comprises a first electrode connected to the first signal line, a second electrode connected to the second signal line, and a switch memory between the first electrode and the second electrode.

20. A semiconductor device comprising:
a first bit line extending in a first direction;
a word line on the first bit line, extending in a second direction crossing the first direction, and spaced apart from the first bit line in a third direction perpendicular to the first direction and the second direction;
a second bit line on the word line, extending in the first direction, and spaced apart from the first bit line and the word line in the third direction, wherein the word line is between the first bit line and the second bit line;
a first memory cell between the first bit line and the word line;
a second memory cell between the word line and the second bit line;
a first insulating layer on a surface of the first bit line facing the word line, at least partially surrounding the first memory cell, and comprising a first layer; and
a second insulating layer on a surface of the second bit line facing the word line, at least partially surrounding the second memory cell, and comprising a second layer including a low-k dielectric material;
wherein the first layer comprises a material having a higher dielectric constant than the low-k dielectric material of the second layer, and
wherein the first layer overlaps the second layer in the third direction.
